(19) United States
(12) Patent Application Publication
(10) Pub. No.: US 2026/0033225 A1
(43) Pub. Date: Jan. 29, 2026

(54) DISPLAY PANEL AND MANUFACTURING METHOD OF THE SAME

(71) Applicant: HKC CORPORATION LIMITED, SHENZHEN (CN)

(72) Inventors: Dongmei WEI, SHENZHEN (CN); Tien-Chun HUANG, SHENZHEN (CN); Chuan WU, SHENZHEN (CN); Zhonglin CAO, SHENZHEN (CN); Wenyu YI, SHENZHEN (CN); Jie CHEN, SHENZHEN (CN); Lidan YE, SHENZHEN (CN)

(73) Assignee: HKC CORPORATION LIMITED, SHENZHEN (CN)

(21) Appl. No.: 19/267,567

(22) Filed: Jul. 13, 2025

(30) Foreign Application Priority Data
Jul. 23, 2024 (CN) 202410997181.3

(51) Int. Cl. H10K 59/88; H10K 59/12; H10K 59/127; H10K 59/80

(52) U.S. Cl. CPC H10K 59/88; H10K 59/1201; H10K 59/1275; H10K 59/873

(57) ABSTRACT

A display panel and a manufacturing method of the same. The display panel includes: a light-emitting unit carrier plate, a drive circuit backplate, and an alignment structure. The light-emitting unit carrier plate includes a glass substrate and light-emitting devices; the glass substrate includes first hole portions; each light-emitting device includes an anode film layer, a light-emitting layer, a cathode film layer, an anode conductive portion, and a cathode conductive portion. The drive circuit backplate includes a silicon-based substrate, a drive circuit layer, and a protective layer; the protective layer includes second hole portions, and the drive circuit layer includes connecting portions. The alignment structure includes a first alignment structure and a second alignment structure. When the light-emitting unit carrier plate and the drive circuit backplate are connected, the anode and cathode conductive portions are connected to the connecting portions, and the first and second alignment structures are mated.

### CROSS-REFERENCE TO RELATED APPLICATIONS

The present application claims priority of Chinese Patent Application No. 202410997181.3, filed on Jul. 23, 2024, the entire contents of which are hereby incorporated by reference in their entirety.

### TECHNICAL FIELD

The present disclosure relates to the field of optical display technologies, and in particular to a display panel and a manufacturing method of the same.

### BACKGROUND

A Silicon-based micro display is characterized by a monocrystalline silicon substrate with a Complementary Metal Oxide Semiconductor (CMOS)-driven circuit integrated into a backplate, which offers enhanced integration and predominantly adopts a top-emitting configuration. Current silicon-based micro displays encompass four primary forms: Digital Micromirror Devices (DMDs), Silicon-based Liquid Crystal Displays (SiLCDs), Silicon-based Organic Light-Emitting (SiOLED) devices, and Silicon-based Diode Light-Emitting (SIDLED) devices. Due to their compact dimensions, optical systems are typically required to achieve wide-field display effects, for enabling near-eye display applications.

Among these, Organic Light-Emitting Displays (OLEDs) exhibit the superior performance in AR/VR applications. Compared to conventional active-matrix organic light-emitting diodes (AMOLEDs) utilizing amorphous silicon, microcrystalline silicon, or low-temperature polycrystalline silicon thin-film transistors as backplates, single-crystal silicon backplates provide significantly higher carrier mobility. The above display devices are AMOLED display devices made using CMOS devices as drive units, integrating traditional external display chips into a silicon-based backplate. During fabrication, a pixel-patterned isolation layer is vapor-deposited on the silicon-based CMOS drive substrate, followed by sequential vapor-deposition of an anode film, light-emitting layer, and cathode film to form subpixels. However, the vapor-deposition processes for depositing subpixels may compromise the integrity of the silicon backplate, thereby increasing production costs.

### SUMMARY OF THE DISCLOSURE

The purpose of the present disclosure is to provide a display panel and a manufacturing method of the same.

A display panel, including:
a light-emitting unit carrier plate, including a glass substrate and light-emitting devices; wherein the glass substrate includes first hole portions, and the light-emitting devices are disposed on the glass substrate; each of the light-emitting devices includes an anode film layer, a light-emitting layer, and a cathode film layer that are stacked in sequence; each of the light-emitting devices further includes an anode conductive portion and a cathode conductive portion, wherein the anode conductive portion is connected to the anode film layer, the cathode conductive portion is connected to the cathode film layer, and the anode conductive portion and the cathode conductive portion both extend into the first hole portions;
a drive circuit backplate, including a silicon-based substrate, a drive circuit layer, and a protective layer; wherein the drive circuit layer is disposed on the silicon-based substrate, and the protective layer is disposed on the drive circuit layer; the protective layer includes second hole portions, and the drive circuit layer includes connecting portions passing through the second hole portions; and
an alignment structure, including a first alignment structure and a second alignment structure; the first alignment structure is disposed on a side of the glass substrate away from the light-emitting device, and the first alignment structure is located outside the light-emitting devices in a radial direction; the second alignment structure is disposed on a side of the protective layer away from the drive circuit layer, and the second alignment structure is located outside the drive circuit layer in the radial direction;
wherein in a case where the light-emitting unit carrier plate and the drive circuit backplate are connected together, the anode conductive portion and the cathode conductive portion are respectively connected to the connecting portions, and the first alignment structure and the second alignment structure are mated with each other.

A manufacturing method of a display panel, including:
preparing a light-emitting unit carrier plate, including:
   forming first hole portions on a glass substrate;
   forming light-emitting devices on a side of the glass substrate; wherein each of the light-emitting devices includes an anode film layer, a light-emitting layer, and a cathode film layer that are stacked in sequence; the light-emitting device further includes an anode conductive portion and a cathode conductive portion; the anode conductive portion is connected to the anode film layer, and the cathode conductive portion is connected to the cathode film layer; the anode conductive portion and the cathode conductive portion both extend into the first hole portions; and
   forming a first alignment structure on a side of the glass substrate away from the light-emitting device, with the first alignment structure located outside the light-emitting device in a radial direction;
preparing a drive circuit backplate, including:
   forming a drive circuit layer on a silicon-based substrate;
   forming a protective layer on the drive circuit layer; the protective layer includes second opening portions, and the drive circuit layer includes connecting portions passing through the second opening portions; and
   forming a second alignment structure on a side of the protective layer away from the drive circuit layer, with the second alignment structure located outside the drive circuit layer in the radial direction; and
connecting the light-emitting unit carrier plate and the drive circuit backplate together, with the anode conductive portion and the cathode conductive portion respectively connected to the connecting portions, and the first alignment structure and the second alignment structure mated with each other.

### BRIEF DESCRIPTION OF THE DRAWINGS

The accompanying drawings are incorporated into the specification and form an integral part thereof, illustrating embodiments of the present disclosure and, together with the specification, serving to explain the principles of the present disclosure. It will be apparent from the accompanying drawings that the embodiments described herein are merely some examples of the present disclosure, and that other drawings may be obtained by those skilled in the art without creative labor based on these drawings.

FIG. 1 is a cross-sectional structural schematic view of a display panel according to some embodiments of the present disclosure.

FIG. 2 is a cross-sectional structural schematic view of a display panel according to other embodiments of the present disclosure.

FIG. 3 is a cross-sectional structural schematic view of an alignment structure according to some embodiments of the present disclosure.

FIG. 4 is a cross-sectional structural schematic view of an alignment structure according to other embodiments of the present disclosure.

FIG. 5 is a flowchart of a manufacturing method of a display panel according to some embodiments of the present disclosure.

FIG. 6 is a flowchart of operation S100 in the manufacturing method according to some embodiments of the present disclosure.

FIG. 7 is a cross-sectional structural schematic view of a light-emitting unit carrier plate according to some embodiments of the present disclosure.

FIG. 8 is a flowchart of operation S200 in the manufacturing method according to some embodiments of the present disclosure.

FIG. 9 is a cross-sectional schematic view of a drive circuit backplate according to some embodiments of the present disclosure.

### DETAILED DESCRIPTION

The exemplary embodiments will now be described in greater detail with reference to the accompanying drawings. However, the exemplary embodiments may be implemented in various forms and should not be limited to the examples described herein; rather, the provision of these embodiments is intended to make the present disclosure more comprehensive and complete and to convey the concept of the exemplary embodiments to those skilled in the art.

Furthermore, the features, structures, or characteristics described may be combined in any suitable manner in one or more embodiments. In the following description, many specific details are provided to give a thorough understanding of the embodiments of the present disclosure. However, those skilled in the art will realize that the technical solutions of the present disclosure may be practiced without one or more of the specific details, or that other methods, components, devices, steps, etc. may be used. In other cases, well-known methods, apparatuses, implementations, or operations are not shown or described in detail to avoid obscuring the various aspects of the present application.

The present disclosure is further described below with reference to the accompanying drawings and specific embodiments. It should be noted that the technical features described in the various embodiments of the present disclosure may be combined with each other as long as they do not conflict with each other. The embodiments described below with reference to the accompanying drawings are exemplary and are intended to explain the present disclosure and should not be understood as limiting the present disclosure.

It should be noted that “multiple” as used herein refers to two or more. “And/or” describes a relationship between associated objects, indicating that three relationships may exist. For example, “A and/or B” may indicate: A exists alone, A and B exist together, or B exists alone. The character “/” generally indicates that the associated objects before and after it are in an “or” relationship.

A Silicon-based micro display is characterized by a monocrystalline silicon substrate with a Complementary Metal Oxide Semiconductor (CMOS)-driven circuit integrated into a backplate, which offers enhanced integration and predominantly adopts a top-emitting configuration. Current silicon-based micro displays encompass four primary forms: Digital Micromirror Devices (DMDs), Silicon-based Liquid Crystal Displays (SiLCDs), Silicon-based Organic Light-Emitting (SiOLED) devices, and Silicon-based Diode Light-Emitting (SIDLED) devices. Due to their compact dimensions, optical systems are typically required to achieve wide-field display effects, for enabling near-eye display applications.

Among these, Organic Light-Emitting Displays (OLEDs) exhibit the superior performance in AR/VR applications. Compared to conventional active-matrix organic light-emitting diodes (AMOLEDs) utilizing amorphous silicon, microcrystalline silicon, or low-temperature polycrystalline silicon thin-film transistors as backplates, single-crystal silicon backplates provide significantly higher carrier mobility. The above display devices are AMOLED display devices made using CMOS devices as drive units, integrating traditional external display chips into a silicon-based backplate. During fabrication, a pixel-patterned isolation layer is vapor-deposited on the silicon-based CMOS drive substrate, followed by sequential vapor-deposition of an anode film, light-emitting layer, and cathode film to form subpixels. However, the vapor-deposition processes for depositing subpixels may compromise the integrity of the silicon backplate, thereby increasing production costs.

To address the above technical issues, referring to FIG. 1, the present disclosure provides a display panel and a manufacturing method of the same, including a light-emitting unit carrier plate 10, a drive circuit backplate 20, and an alignment structure 30. The light-emitting unit carrier plate 10 and the drive circuit backplate 20 are positioned and protected by the alignment structure 30. Since the light-emitting unit carrier plate 10 and the drive circuit backplate 20 are assembled via the alignment structure 30, a direct vapor-deposition of an anode film layer 121, a light-emitting layer 122, and a cathode film layer 123 on the drive circuit backplate 20 is avoided, thereby reducing the risk of damage to the drive circuit and lowering costs.

In some embodiments, referring to FIG. 1, the light-emitting unit carrier plate 10 includes a glass substrate 11 and light-emitting devices 12. The glass substrate 11 includes first hole portions 111, and the light-emitting devices 12 are disposed on the glass substrate 11. Each light-emitting device 12 includes an anode film layer 121, a light-emitting layer 122, and a cathode film layer 123 stacked in sequence. The light-emitting device 12 further includes an anode conductive portion 124 and a cathode conductive portion 125, where the anode conductive portion 124 is connected to the anode film layer 121, the cathode conductive portion 125 is connected to the cathode film layer 123, and the anode conductive portion 124 and the cathode conductive portion 125 both extend into the first hole portions 111. The drive circuit backplate 20 includes a silicon-based substrate 21, a drive circuit layer 22, and a protective layer 23. The drive circuit layer 22 is disposed on the silicon-based substrate 21, and the protective layer 23 is disposed on the drive circuit layer 22. The protective layer 23 includes second hole portions 231, and the drive circuit layer 22 includes connecting portions 221, which pass through the second hole portions 231. The alignment structure 30 includes a first alignment structure 31 and a second alignment structure 32. The first alignment structure 31 is disposed on a side of the glass substrate 11 away from the light-emitting device 12, and the first alignment structure 31 is located outside the light-emitting device 12 in a radial direction X1; the second alignment structure 32 is disposed on a side of the protective layer 23 away from the drive circuit layer 22, and the second alignment structure 32 is located outside the drive circuit layer 22 in the radial direction X1. When the light-emitting unit carrier plate 10 and the drive circuit backplate 20 are connected together, the anode conductive portion 124 and the cathode conductive portion 125 are respectively connected to the connecting portions 221, and the first alignment structure 31 and the second alignment structure 32 are mated with each other.

In the embodiments, referring to FIG. 1, the cathode conductive portion 125 and the anode conductive portion 124 disposed within the first hole portions 111 are connected to the connecting portions 221 disposed within the second hole portions 231, such that electrical signals from the drive circuit backplate 20 are transmitted through the connecting portions 221, the anode conductive portion 124, and the cathode conductive portion 125 to the anode film layer 121 and the cathode film layer 123, respectively, thereby causing the light-emitting layer 122 to emit light. Furthermore, the first alignment structure 31 is disposed outside the light-emitting device 12 in the radial direction X1, and the second alignment structure 32 is disposed outside the drive circuit layer 22 in the radial direction X1. When the anode conductive portion 124 and the cathode conductive portion 125 are connected to the connecting portions 221, the first alignment structure 31 and the second alignment structure 32 are mated with each other, so as to achieve alignment between the light-emitting unit carrier plate 10 and the drive circuit backplate 20 and to protect the drive circuit layer 22, the anode conductive portion 124, and the cathode conductive portion 125, thereby reducing the risk of moisture and dust ingress.

In some embodiments, the glass substrate 11 may improve the light transmittance of the display panel and increase the brightness of the display panel. The first hole portions 111 are provided on the glass substrate 11, specifically, the first hole portions 111 may be defined on the glass substrate 11 through exposure, development, and etching. The specific method for performing exposure, development, and etching on the glass substrate 11 is not limited herein and may be selected based on actual conditions.

In some embodiments, the anode film layer material, light-emitting layer material, and cathode film layer material of the light-emitting device 12 are not specifically defined herein and are selected based on actual conditions. During fabrication, after defining pixel openings on the glass substrate 11 through exposure, development, and etching, the anode film layer material is first vapor-deposited to form the anode film layer 121, then the light-emitting layer material is vapor-deposited to form the light-emitting layer 122, and finally the cathode film layer material is vapor-deposited to form the cathode film layer 123.

In some embodiments, the pixel openings may be configured as the first opening portions 111 or as spaces between isolation structures 126. The formation of the isolation structures 126 is described in detail below.

In some embodiments, during the vapor-deposition process, the anode film layer 121, the light-emitting layer 122, and the cathode film layer 123 may be vapor-deposited at different vapor-deposition angles to ensure that the anode film layer 121, the light-emitting layer 122, and the cathode film layer 123 have different areas within the pixel opening.

In some embodiments, referring to FIG. 1, the anode conductive portion 124 and the cathode conductive portion 125 are configured to enable an electrical conduction between the anode film layer 121, the cathode film layer 123, and the drive circuit backplate 20. Since the anode film layer 121 and the cathode film layer 123 require power supply from the drive circuit backplate 20, and the drive circuit backplate 20 is disposed on the side of the glass substrate 11 away from the light-emitting device 12, the anode conductive portion 124 and the cathode conductive portion 125 are disposed within the first hole portion 111 and extend toward the drive circuit backplate 20.

In some embodiments, referring to FIG. 1, the anode conductive portion 124 may be formed by vapor-deposition within the first hole portion 111 prior to forming the anode film layer 121, or may be formed by vapor-deposition within the first hole portion 111 after forming the anode film layer 121. To facilitate encapsulation of the cathode conductive portion 125, the cathode conductive portion 125 and the cathode film layer material may be simultaneously vapor-deposited, followed by exposure, development, and etching of the cathode film layer material to simultaneously form the cathode conductive portion 125 and the cathode film layer 123.

In some embodiments, the anode conductive portion 124 and the anode film layer 121 may be a one-piece structure, with the anode film layer material deposited in the pixel openings, etched to form the anode film layer 121, and a portion of the anode film layer material located within the first hole portion 111 configured as the anode conductive portion 124. The cathode conductive portion 125 and the cathode film layer 123 may be a one-piece structure. During preparation of the cathode film layer 123, the cathode film layer material is deposited in the pixel openings, followed by exposure, development, and etching to form the cathode film layer 123, with a portion of the cathode film layer material located within the first hole portion 111 configured as the cathode conductive portion 125. In other embodiments, a corresponding pair of the anode conductive portion 124 and the anode film layer 121 may be formed separately, and then the anode conductive portion 124 and anode film layer 121 are arranged in contact; alternatively, a corresponding pair of the cathode conductive portion 125 and the cathode film layer 123 may be formed separately, and then the cathode conductive portion 125 and cathode film layer 123 are arranged in contact. The specific process method is selected based on actual conditions.

In some embodiments, the silicon-based substrate 21 is configured to be a single-crystal silicon substrate, the drive circuit layer 22 includes multiple active organic light-emitting diode display devices arranged with CMOS devices as drive units, and the protective layer 23 is configured to be an organic protective layer or an inorganic protective layer with insulating properties. Specifically, the protective layer 23 is configured as a SiO₂ layer. The silicon-based substrate 21, the drive circuit layer 22, and the protective layer 23 may be designed according to actual conditions.

In some embodiments, the first alignment structure 31 may be welded to the glass substrate 11; or be formed on the glass substrate 11 through processes such as deposition or etching; or be formed by first forming another film layer (such as an insulating layer 40 described below) on the glass substrate 11, then drilling a hole in the film layer, and finally depositing the first alignment structure 31 on the hole. The specific process method for preparing the first alignment structure 31 is selected based on actual conditions.

In some embodiments, referring to FIG. 1, the display panel further includes an encapsulation layer 50, which is disposed on the cathode film layer 123 and is configured to encapsulate the light-emitting device 12 on the glass substrate 11. The material, thickness, and process of the encapsulation layer 50 are not specifically limited here and are selected based on actual conditions.

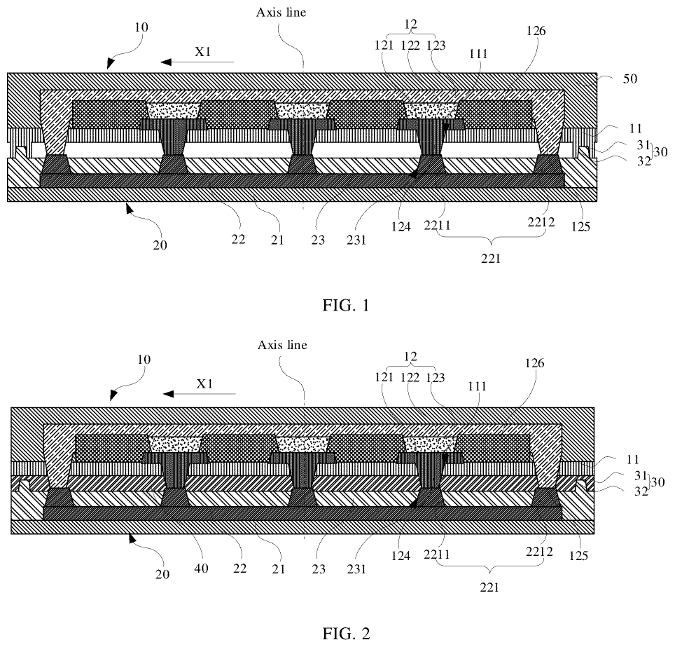

In some embodiments, referring to FIG. 2, the light-emitting unit carrier plate 10 further includes an insulating layer 40, which is disposed on a side of the glass substrate 11 away from the light-emitting device 12. The first alignment structure 31 is arranged on a side of the insulating layer 40 away from the glass substrate 11. The insulating layer 40 is made of an organic insulating material, and the first alignment structure 31 is arranged on the insulating layer 40 and faces the drive circuit backplate 20. Additionally, to achieve electrical connection between the light-emitting unit carrier plate 10 and the drive circuit backplate 20, holes are defined in the insulating layer 40 to provide hole structures communicating with the first hole portions 111, allowing the anode conductive portion 124 and the cathode conductive portion 125 to extend into the hole structures in the insulating layer 40 and be connected with the connecting portions 221 to achieve electrical connection.

In some embodiments, referring to FIG. 2, the second alignment structure 32 may be welded to the drive circuit layer 22; or be formed on the drive circuit layer 22 through processes such as deposition or etching; or be formed by etching the protective layer 23. The specific process method for preparing the first alignment structure 31 is selected based on actual conditions.

In some embodiments, referring to FIG. 2, the radial direction X1 is in a radial plane along an axis line, where the axis line is configured as an axis line of the light-emitting device 12. To provide more comprehensive protection for the drive circuit layer 22, the anode conductive portion 124, and the cathode conductive portion 125, the first alignment structure 31 is disposed outside the light-emitting device 12 in the radial direction X1, and the second alignment structure 32 is disposed outside the drive circuit layer 22 in the radial direction X1.

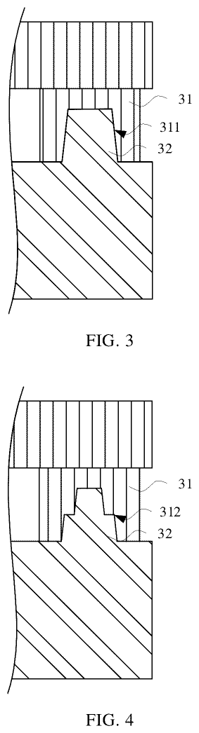

In some embodiments, referring to FIG. 2, the first alignment structure 31 is a recessed structure, and the second alignment structure 32 is a protruding structure. When the light-emitting unit carrier plate 10 and the drive circuit backplate 20 are connected together, the protruding structure extends into the recessed structure. Specifically, the recessed structure may be a straight recessed structure 311 (referring to FIG. 3) or a stepped recessed structure 312 (referring to FIG. 4), and the protruding structure is configured to adapt to the shape of the straight recessed structure 311 or the stepped recessed structure 312. Specifically, the mating error between the recessed structure and the protruding structure is kept sufficiently small to achieve better positioning, ensuring that the anode conductive portion 124, the cathode conductive portion 125, and the connecting portion 221 are mated more accurately. Additionally, the recessed structure and the protruding structure have a larger contact area, resulting in a larger scaling area, which enhances the sealing performance after they are mated.

In some embodiments, referring to FIG. 2, the light-emitting device 12 further includes isolation structures 126 that are spaced apart. A spacing between each adjacent two isolation structures 126 is in communication with a corresponding first hole portion 111. The anode film layer 121 and the light-emitting layer 122 are stacked in sequence at a corresponding spacing between corresponding isolation structures 126. The cathode film layer 123 is disposed on the light-emitting layer 122 and extends outside the spacings between the isolation structures 126 to cover the isolation structures 126, such that the anode conductive portion 124 and cathode conductive portion 125 disposed in the first hole portion 111 are in contact with the anode film layer 121 and cathode film layer 123, respectively. The isolation structure 126 is configured to achieve separate encapsulation of the anode film layer 121, the light-emitting layer 122, and the cathode film layer 123 of each individual light-emitting device 12. The isolation structure 126 may be made of organic materials or inorganic materials. The organic materials may specifically include polyimide, and the inorganic materials may specifically include silicon dioxide. Other organic materials and inorganic materials may be selected as appropriate. The isolation structures 126 may be radially spaced apart in the radial direction X1 to form an enclosing structure, such that the spaced-apart regions (the above spacings) each form a ring-shaped structure, and the anode film layer 121, the light-emitting layer 122, and the cathode film layer 123 are deposited on the ring-shaped structure.

In some embodiments, the spacing having the ring-shaped structure is in communication with the first hole portion 111 to electrically connect the anode film layer 121 and the anode conductive portion 124. The spacing having the ring-shaped structure may or may not have the same axis as the first hole portion 111.

In some embodiments, referring to FIG. 2, the anode film layer 121 and the light-emitting layer 122 are disposed at each spacing, and the cathode film layer 123 covers the light-emitting layers 122 and the isolation structures 126 to form an integrated film layer structure. The anode film layer 121 at each spacing is electrically connected to the drive circuit backplate 20 via corresponding anode conductive portion 124, while the cathode film layer 123 is electrically connected to the drive circuit backplate 20 via the cathode conductive portion 125. This design reduces the thickness of the display panel, making it lighter in weight.

In some embodiments, referring to FIG. 2, some of the first hole portions 111 are each configured to accommodate the anode conductive portion 124, and some of the first hole portions 111 are each configured to accommodate the cathode conductive portion 125. In the radial direction X1, the first hole portion 111 configured to accommodate the cathode conductive portion 125 is located outside the first hole portion 111 configured to accommodate the anode conductive portion 124. In the radial direction X1, the cathode conductive portion 125 is disposed outside the anode conductive portion 124, such that the cathode conductive portion 125 surrounds the anode conductive portion 124 to supply power to the entire cathode film layer 123. The number of the cathode conductive portions 125 and the anode conductive portions 124 is set according to actual conditions.

In some embodiments, referring to FIG. 2, the connecting portion 221 includes a first connecting portion 2211 and a second connecting portion 2212. In the radial direction X1, the second connecting portion 2212 is located outside the first connecting portion 2211, and the first connecting portion 2211 and the second connecting portion 2212 pass through the second hole portions 231 of the protective layer 23. The anode conductive portion 124 is connected to the first connecting portion 2211, and the cathode conductive portion 125 is connected to the second connecting portion 2212. The first connecting portion 2211 can transmit an anode signal through the anode conductive portion 124, and the second connecting portion 2212 can transmit a cathode signal through the cathode conductive portion 125, thereby enabling the light-emitting device 12 to emit light.

In some embodiments, the first hole portion 111 gradually decreases in size from a side closer to the light-emitting device 12 toward a side farther from the light-emitting device 12. The second hole portion 231 gradually decreases in size from a side closer to the drive circuit layer 22 toward a side farther from the drive circuit layer 22. Limited to the process of forming the first hole portion 111 and the second hole portion 231 on the glass and the organic layer, such a design may facilitates the fabrication of the first hole portion 111 and the second hole portion 231 and further facilitate the preparation of the anode conductive portion 124 and the cathode conductive portion 125 in subsequent processes.

In the present disclosure, the drive circuit backplate 20 transmits electrical signals to the anode via the anode conductive portion 124 and transmits electrical signals to the cathode via the cathode conductive portion 125, thereby causing the light-emitting device 12 to emit light. The first alignment structure 31 is a recessed structure, and the second alignment structure 32 is a protruding structure. When the light-emitting unit carrier plate 10 and the drive circuit backplate 20 are connected together, the protruding structure extends into the recessed structure. When the anode conductive portion 124 and the cathode conductive portion 125 are connected to the connecting portions 221, respectively, the first alignment structure 31 and the second alignment structure 32 cooperate with each other, thereby achieving alignment between the light-emitting unit carrier plate 10 and the drive circuit backplate 20, and providing protection for the drive circuit layer 22, the anode conductive portion 124, and the cathode conductive portion 125, thereby reducing the risk of moisture and dust ingress.

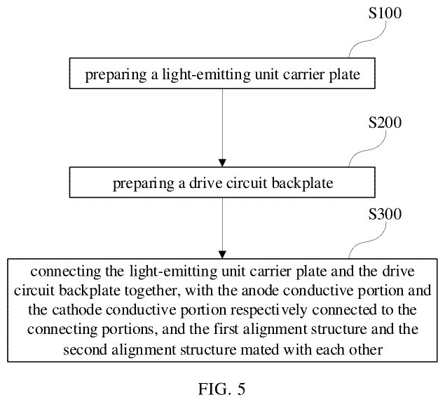

Referring to FIG. 5, the present disclosure further provides a manufacturing method of a display panel, for producing the aforementioned display panel. The manufacturing method specifically includes the following operations S100 to S300.

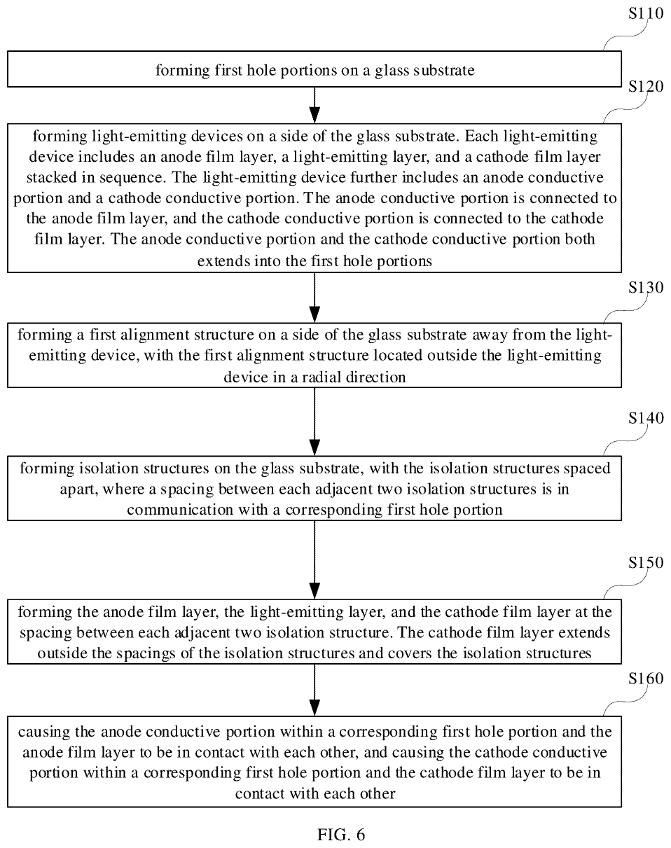

At block S100: preparing a light-emitting unit carrier plate 10. Referring to FIG. 6, the method for preparing the light-emitting unit carrier plate 10 specifically includes operations S110 to S130:

At block S110: forming first hole portions 111 on a glass substrate 11.

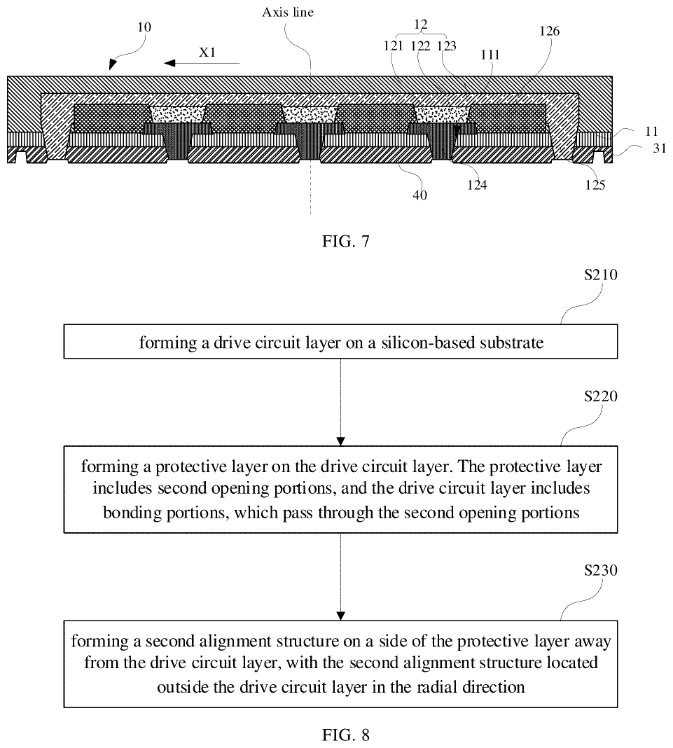

Referring to FIG. 7, a mask is applied to coat photoresist on the glass substrate 11, followed by exposure and development to form the shape of the first hole portions 111. The shape of the first hole portions 111 is then etched to form the first hole portions 111, and the photoresist is removed. The type of photoresist and etching solution are selected based on actual conditions and are not specifically limited herein. Depending on actual conditions, the glass substrate 11 may further require cleaning and drying.

At block S120: forming light-emitting devices 12 on a side of the glass substrate 11. Each light-emitting device 12 includes an anode film layer 121, a light-emitting layer 122, and a cathode film layer 123 stacked in sequence. The light-emitting device 12 further includes an anode conductive portion 124 and a cathode conductive portion 125. The anode conductive portion 124 is connected to the anode film layer 121, and the cathode conductive portion 125 is connected to the cathode film layer 123. The anode conductive portion 124 and the cathode conductive portion 125 both extend into the first hole portions 111.

Referring to FIG. 7, an anode film layer material, a light-emitting layer, and a cathode film layer material are sequentially vapor-deposited in the region corresponding to the first hole portions 111 of the glass substrate 11, to form the anode film layer 121, the light-emitting layer 122, and the cathode film layer 123 in the region corresponding to each first hole portion 111. The anode conductive portion 124 and the cathode conductive portion 125 are formed within the first hole portion 111, such that the anode conductive portion 124 is connected to the anode film layer 121 and the cathode conductive portion 125 is connected to the cathode film layer 123. The anode conductive portion 124 and the anode film layer 121 may be a one-piece structure or separate structures that are electrically connected, and the cathode conductive portion 125 and the cathode film layer 123 may be a one-piece structure or separate structures that are electrically connected.

At block S130: forming a first alignment structure 31 on a side of the glass substrate 11 away from the light-emitting device 12, with the first alignment structure 31 located outside the light-emitting device 12 in a radial direction X1.

Referring to FIG. 7, the first alignment structure 31 may be welded to the glass substrate 11; or be formed on the glass substrate 11 through processes such as deposition or etching; or be formed by depositing on another film layer formed on the glass substrate 11 after drilling a hole in the film layer. The specific process method for preparing the first alignment structure 31 is selected based on actual conditions.

At block S200: preparing a drive circuit backplate 20. Referring to FIG. 8, the method for preparing the drive circuit backplate 20 specifically includes operations S210 to S230.

At block S210: forming a drive circuit layer 22 on a silicon-based substrate 21.

The drive circuit layer 22 is a CMOS circuit. The preparation method of the CMOS circuit is not specifically defined here and is selected based on actual conditions.

At block S220: forming a protective layer 23 on the drive circuit layer 22. The protective layer 23 includes second opening portions 231, and the drive circuit layer 22 includes connecting portions 221, which pass through the second opening portions 231.

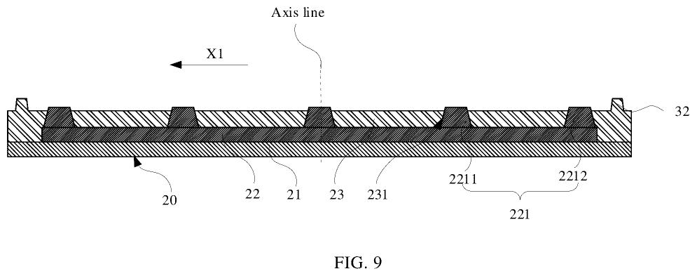

Referring to FIG. 9, the protective layer 23 is configured to be an organic protective layer and/or an inorganic protective layer with insulating properties. Specifically, the protective layer 23 is configured as a SiO₂ layer. The connecting portion 221 may be formed on the drive circuit by welding, deposition, or other methods. The protective layer 23 is deposited on the drive circuit layer 22 and caused to form the second opening portions 231 corresponding to the connecting portions 221.

At block S230: forming a second alignment structure 32 on a side of the protective layer 23 away from the drive circuit layer 22, with the second alignment structure 32 located outside the drive circuit layer 22 in the radial direction X1.

Referring to FIG. 9, the second alignment structure 32 may be welded to the drive circuit layer 22; or be formed on the drive circuit layer 22 through processes such as deposition or etching; or be formed by etching the protective layer 23. When the second alignment structure 32 is formed by welding, deposition, or etching processes, corresponding hole structures must be formed on the protective layer 23 to allow the second alignment structure 32 to pass through the protective layer 23. When the second alignment structure 32 is formed by etching the protective layer 23, the protective layer 23 must be deposited to a sufficient thickness, exposed, and developed to form the shape of the second alignment structure 32, followed by etching to obtain the second alignment structure 32, which is protruding from the protective layer 23.

At block S300: connecting the light-emitting unit carrier plate 10 and the drive circuit backplate 20 together, with the anode conductive portion 124 and the cathode conductive portion 125 respectively connected to the connecting portions 221, and the first alignment structure 31 and the second alignment structure 32 mated with each other.

Referring to FIGS. 7 and 9, when the anode conductive portion 124 and the cathode conductive portion 125 are connected to the connecting portions 221, respectively, the first alignment structure 31 and the second alignment structure 32 are mated with each other, thereby achieving alignment between the light-emitting unit carrier plate 10 and the drive circuit backplate 20, and further protect the drive circuit layer 22, the anode conductive portion 124, and the cathode conductive portion 125, reducing the risk of water vapor and dust ingress.

In some embodiments, referring to FIGS. 7 and 9, the first alignment structure 31 is a recessed structure, and the second alignment structure 32 is a protruding structure. When the light-emitting unit carrier plate 10 and the drive circuit backplate 20 are connected together, the protruding structure extends into the recessed structure. The recessed structure may be a straight recessed structure 311 (referring to FIG. 3) or a stepped recessed structure 312 (referring to FIG. 4), and the protruding structure is configured to adapt to the shape of the straight recessed structure 311 or the stepped recessed structure 312. The mating error between the recessed structure and the protruding structure is kept sufficiently small to achieve better positioning, ensuring that the anode conductive portion 124, the cathode conductive portion 125, and the connecting portion 221 are mated more accurately. Additionally, the recessed structure and the protruding structure have a larger contact area, resulting in a larger scaling area, which enhances the sealing performance after they are mated.

In some embodiments, the manufacturing method further includes: forming an insulating layer 40 on a side of the glass substrate 11 away from the light-emitting device 12. The first alignment structure 31 is arranged on a side of the insulating layer 40 away from the glass substrate 11. The insulating layer 40 is made of an organic insulating material, and the first alignment structure 31 is arranged on the insulating layer 40 and faces the drive circuit backplate 20. Additionally, to achieve electrical connection between the light-emitting unit carrier plate 10 and the drive circuit backplate 20, holes are defined in the insulating layer 40 to provide hole structures communicating with the first hole portions 111, allowing the anode conductive portion 124 and the cathode conductive portion 125 to extend into the hole structures in the insulating layer 40 and be connected with the connecting portions 221 to achieve electrical connection.

In some embodiments, referring to FIG. 6, the method for preparing the light-emitting device 12 further includes operations S140 to S160.

At block S140: forming isolation structures 126 on the glass substrate 11, with the isolation structures 126 spaced apart, where a spacing between each adjacent two isolation structures 126 is in communication with a corresponding first hole portion 111.

The isolation structures 126 may be formed on the glass substrate 11 through exposure, development, and etching, and the specific method is not limited herein. The isolation structure 126 may be made of organic materials or inorganic materials. The organic materials may specifically include polyimide, and the inorganic materials may specifically include silicon dioxide. Other organic materials and inorganic materials may be selected as appropriate.

At block S150: forming the anode film layer 121, the light-emitting layer 122, and the cathode film layer 123 at the spacing between each adjacent two isolation structures 126. The cathode film layer 123 extends outside the spacings of the isolation structures 126 and covers the isolation structures 126.

Referring to FIG. 7, the anode film layer 121 and the light-emitting layer 122 are disposed at each spacing, the cathode film layer 123 covers the light-emitting layers 122 and the isolation structures 126 to form an integrated film layer structure. The anode at each spacing is electrically connected to the drive circuit backplate 20 via corresponding anode conductive portions 124, while the cathode film layer 123 is electrically connected to the drive circuit backplate 20 via the cathode conductive portion 125. This design reduces the thickness of the display panel, making it lighter in weight.

At block S160: causing the anode conductive portion 124 within a corresponding first hole portion 111 and the anode film layer 121 to be in contact with each other, and causing the cathode conductive portion 125 within a corresponding first hole portion 111 and the cathode film layer 123 to be in contact with each other.

Referring to FIGS. 7 and 9, when the light-emitting unit carrier plate 10 and the drive circuit backplate 20 are connected, the drive circuit backplate 20 transmits electrical signals to the anode via the anode conductive portion 124 and transmits electrical signals to the cathode via the cathode conductive portion 125, causing the light-emitting device 12 to emit light.

In the present disclosure, the drive circuit backplate 20 transmits electrical signals to the anode via the anode conductive portion 124 and transmits electrical signals to the cathode via the cathode conductive portion 125, thereby causing the light-emitting device 12 to emit light. The first alignment structure 31 is a recessed structure, and the second alignment structure 32 is a protruding structure. When the light-emitting unit carrier plate 10 and the drive circuit backplate 20 are connected together, the protruding structure extends into the recessed structure. When the anode conductive portion 124 and the cathode conductive portion 125 are connected to the connecting portions 221, respectively, the first alignment structure 31 and the second alignment structure 32 cooperate with each other, thereby achieving alignment between the light-emitting unit carrier plate 10 and the drive circuit backplate 20, and providing protection for the drive circuit layer 22, the anode conductive portion 124, and the cathode conductive portion 125, thereby reducing the risk of moisture and dust ingress.

In the present disclosure, unless otherwise explicitly specified or limited, terms such as “arranged with,” “connected,” etc., should be interpreted broadly. For example, they may refer to fixed connections, removable connections, or integral structures; mechanical connections or electrical connections; direct connections or indirect connections via intermediate media; or internal communication between two components or an interactive relationship between two components. For those skilled in the art, the specific meaning of the above terms herein may be understood based on the specific circumstances.

In the description of this specification, the terms “some embodiments” and the like refer to at least one embodiment of the present disclosure that includes the specific features, structures, materials, or characteristics described in the embodiment. In this specification, the illustrative expressions of the above terms are not necessarily directed to the same embodiment or example. Furthermore, the specific features, structures, materials, or characteristics described may be combined in any one or more embodiments or examples in an appropriate manner. Additionally, without being mutually contradictory, those skilled in the art may combine and integrate the different embodiments or examples described in this specification, as well as the features of different embodiments or examples.

Although embodiments of the present disclosure have been shown and described above, it should be understood that the above embodiments are exemplary and not intended to limit the present disclosure. Those skilled in the art may make changes, modifications, replacements, and variations to the above embodiments within the scope of the present disclosure. Therefore, any changes or modifications made in accordance with the claims and description of the present disclosure should be considered within the scope of the present disclosure.

1. A display panel, comprising:
a light-emitting unit carrier plate, comprising a glass substrate and light-emitting devices; wherein the glass substrate comprises first hole portions, and the light-emitting devices are disposed on the glass substrate; each of the light-emitting devices comprises an anode film layer, a light-emitting layer, and a cathode film layer that are stacked in sequence; each of the light-emitting devices further comprises an anode conductive portion and a cathode conductive portion, wherein the anode conductive portion is connected to the anode film layer, the cathode conductive portion is connected to the cathode film layer, and the anode conductive portion and the cathode conductive portion both extend into the first hole portions;
a drive circuit backplate, comprising a silicon-based substrate, a drive circuit layer, and a protective layer; wherein the drive circuit layer is disposed on the silicon-based substrate, and the protective layer is disposed on the drive circuit layer; the protective layer comprises second hole portions, and the drive circuit layer comprises connecting portions passing through the second hole portions; and
an alignment structure, comprising a first alignment structure and a second alignment structure; the first alignment structure is disposed on a side of the glass substrate away from the light-emitting device, and the first alignment structure is located outside the light-emitting devices in a radial direction; the second alignment structure is disposed on a side of the protective layer away from the drive circuit layer, and the second alignment structure is located outside the drive circuit layer in the radial direction;
wherein in a case where the light-emitting unit carrier plate and the drive circuit backplate are connected together, the anode conductive portion and the cathode conductive portion are respectively connected to the connecting portions, and the first alignment structure and the second alignment structure are mated with each other.

2. The display panel according to claim 1, wherein the first alignment structure is a recessed structure, and the second alignment structure is a protruding structure; in a case where the light-emitting unit carrier plate and the drive circuit backplate are connected together, the protruding structure extends into the recessed structure.

3. The display panel according to claim 1, wherein the light-emitting unit carrier plate further comprises an insulating layer disposed on a side of the glass substrate away from the light-emitting device; the first alignment structure is arranged on a side of the insulating layer away from the glass substrate.

4. The display panel according to claim 3, wherein holes are defined in the insulating layer to communicate with the first hole portions.

5. The display panel according to claim 1, wherein the light-emitting device further comprises isolation structures that are spaced apart; a spacing between each adjacent two isolation structures is in communication with a corresponding first hole portion;
wherein the anode film layer and the light-emitting layer are stacked in sequence at the spacing between corresponding adjacent two isolation structure; the cathode film layer is disposed on the light-emitting layer and extends outside the spacings of the isolation structures to cover the isolation structures; the anode conductive portion is caused to be in contact with the anode film layer, and cathode conductive portion is caused to be in contact with the cathode film layer.

6. The display panel according to claim 5, wherein in the radial direction, the cathode conductive portion is disposed outside the anode conductive portion;
the connecting portion comprises a first connecting portion and a second connecting portion; in the radial direction, the second connecting portion is located outside the first connecting portion, and the first connecting portion and the second connecting portion pass through the second hole portions of the protective layer;
the anode conductive portion is connected to the first connecting portion, and the cathode conductive portion is connected to the second connecting portion.

7. The display panel according to claim 1, wherein each of the first hole portions gradually decreases in size from a side closer to the light-emitting device toward a side farther from the light-emitting device; each of the second hole portions gradually decreases in size from a side closer to the drive circuit layer toward a side farther from the drive circuit layer.

8. The display panel according to claim 1, wherein the anode conductive portion and the anode film layer are in a one-piece structure, and the cathode conductive portion and the cathode film layer are in a one-piece structure.

9. The display panel according to claim 1, wherein the silicon-based substrate is configured to be a single-crystal silicon substrate; the drive circuit layer comprises a plurality of active organic light-emitting diode display devices arranged with Complementary Metal Oxide Semiconductor (CMOS) devices as drive units; and the protective layer is configured to be at least one of an organic protective layer and an inorganic protective layer with insulating properties.

10. The display panel according to claim 1, further comprising an encapsulation layer disposed on the cathode film layer and configured to encapsulate the light-emitting devices on the glass substrate.

11. The display panel according to claim 1, wherein the recessed structure is a stepped recessed structure, and the protruding structure is a stepped protruding structure.

12. A manufacturing method of a display panel, comprising:
preparing a light-emitting unit carrier plate, comprising:
forming first hole portions on a glass substrate;
forming light-emitting devices on a side of the glass substrate; wherein each of the light-emitting devices comprises an anode film layer, a light-emitting layer, and a cathode film layer that are stacked in sequence; the light-emitting device further comprises an anode conductive portion and a cathode conductive portion; the anode conductive portion is connected to the anode film layer, and the cathode conductive portion is connected to the cathode film layer; the anode conductive portion and the cathode conductive portion both extend into the first hole portions; and
forming a first alignment structure on a side of the glass substrate away from the light-emitting device, with the first alignment structure located outside the light-emitting device in a radial direction;
preparing a drive circuit backplate, comprising:
forming a drive circuit layer on a silicon-based substrate;
forming a protective layer on the drive circuit layer; the protective layer comprises second opening portions, and the drive circuit layer comprises connecting portions passing through the second opening portions; and
forming a second alignment structure on a side of the protective layer away from the drive circuit layer, with the second alignment structure located outside the drive circuit layer in the radial direction; and
connecting the light-emitting unit carrier plate and the drive circuit backplate together, with the anode conductive portion and the cathode conductive portion respectively connected to the connecting portions, and the first alignment structure and the second alignment structure mated with each other.

13. The manufacturing method according to claim 12, wherein the first alignment structure is a recessed structure, and the second alignment structure is a protruding structure; in a case where the light-emitting unit carrier plate and the drive circuit backplate are connected together, the protruding structure extends into the recessed structure.

14. The manufacturing method according to claim 12, further comprising:
forming an insulating layer on a side of the glass substrate away from the light-emitting device; wherein the first alignment structure is arranged on a side of the insulating layer away from the glass substrate.

15. The manufacturing method according to claim 12, wherein the forming light-emitting devices comprises:
forming isolation structures on the glass substrate, with the isolation structures spaced apart; wherein a spacing between each adjacent two isolation structures is in communication with a corresponding first hole portion;
forming the anode film layer, the light-emitting layer, and the cathode film layer at the spacing between corresponding adjacent two isolation structures; wherein the cathode film layer extends outside the spacings of the isolation structures and covers the isolation structures; and
causing the anode conductive portion and the anode film layer to be in contact with each other, and causing the cathode conductive portion and the cathode film layer to be in contact with each other.

16. A display panel, defining a plurality of anode positions and a plurality of cathode positions; wherein the plurality of anode positions are disposed within a region enclosed by the plurality of cathode positions in a radial direction of the display panel;
wherein the display panel comprises:
a light-emitting unit carrier plate, comprising a glass substrate; wherein the glass substrate comprises first hole portions, some of the first hole portions facing the plurality of anode positions in a one-to-one correspondence and a remaining part of the first hole portions facing the plurality of cathode positions in a one-to-one correspondence; on each anode position, an anode film layer and a light-emitting layer are stacked in sequence on the glass substrate, and an anode conductive portion passes through the corresponding first hole portion and is connected to the anode film layer; a cathode film layer is stacked on and covers all the light-emitting layers on the plurality of anode positions; on each cathode position, the cathode film layer is formed with a cathode conductive portion passing through a corresponding first hole portion; and
a drive circuit backplate, configured to be docked with the light-emitting unit carrier plate and comprising a silicon-based substrate, a drive circuit layer, and a protective layer; wherein the drive circuit layer is disposed on the silicon-based substrate, and the protective layer is disposed on the drive circuit layer; the protective layer comprises second hole portions, and the drive circuit layer comprises connecting portions passing through the second hole portions; some of the second hole portions faces the plurality of anode positions in a one-to-one correspondence and a remaining part of the second hole portions faces the plurality of cathode positions in a one-to-one correspondence;
wherein a side of the light-emitting unit carrier plate facing the drive circuit backplate is arranged with a first alignment structure, and a side of the drive circuit backplate facing the light-emitting unit carrier plate is arranged with a second alignment structure; the first alignment structure and the second alignment structure are farther from the plurality of anode positions than the plurality of cathode positions in the radial direction;
wherein in a case where the light-emitting unit carrier plate and the drive circuit backplate are connected together, the anode conductive portion and the cathode conductive portion are respectively connected to the connecting portions, and the first alignment structure and the second alignment structure are mated with each other.

17. The display panel according to claim 16, wherein the first alignment structure is a recessed structure, and the second alignment structure is a protruding structure; in a case where the light-emitting unit carrier plate and the drive circuit backplate are connected together, the protruding structure extends into the recessed structure.

18. The display panel according to claim 16, wherein the light-emitting unit carrier plate further comprises an insulating layer disposed on a side of the glass substrate away from the light-emitting device; the first alignment structure is arranged on a side of the insulating layer away from the glass substrate.

19. The display panel according to claim 16, wherein the light-emitting device further comprises an isolation structure; the isolation structure defines a plurality of holes passing through the isolation structure and facing the plurality of anode positions and the plurality of cathode positions in a one-to-one correspondence.

20. The display panel according to claim 16, wherein each of the first hole portions gradually decreases in size from a side closer to the light-emitting device toward a side farther from the light-emitting device; each of the second hole portions gradually decreases in size from a side closer to the drive circuit layer toward a side farther from the drive circuit layer.
